(19) United States
(12) Patent Application Publication
(10) Pub. No.: US 2026/0029990 A1
(43) Pub. Date: Jan. 29, 2026

(54) ARITHMETIC CIRCUITRY, MEMORY SYSTEM, AND METHOD OF CONTROLLING NON-VOLATILE MEMORY

(71) Applicant: Kioxia Corporation, Tokyo (JP)

(72) Inventors: Naoaki KOKUBUN, Yokohama (JP); Teruyuki IWASA, Yokohama (JP); Toshiyuki YAMAGISHI, Fuchu (JP)

(73) Assignee: Kioxia Corporation, Tokyo (JP)

(21) Appl. No.: 18/972,331

(22) Filed: Dec. 6, 2024

(30) Foreign Application Priority Data
Jul. 26, 2024 (JP) 2024-121336

(51) Int. Cl. G06F 7/525; H03K 19/21; H03M 13/15

(52) U.S. Cl. CPC G06F 7/525; H03K 19/21; H03M 13/1575

(57) ABSTRACT

Arithmetic circuitry according one embodiment performs a first arithmetic operation by AND operations and XOR operations. The first arithmetic operation corresponds to p multiplications (p is an integer of 2 or more) to be performed in series. The p multiplications are respectively represented by p order-3 tensors each receiving two elements of a Galois field as inputs and outputting one element as a result of multiplication of the two elements. The AND operations calculate AND values of a plurality of elements used in the p multiplications. The XOR operations are based on a contracted tensor obtained by contraction of an order-3p tensor obtained by a direct product of the p order-3 tensors and the AND values.

### CROSS-REFERENCE TO RELATED APPLICATIONS

This application is based upon and claims the benefit of priority from Japanese Patent Application No. 2024-121336, filed on Jul. 26, 2024, the entire contents of which are incorporated herein by reference.

### FIELD

Embodiments described herein relate generally to arithmetic circuitry, a memory system, and a method of controlling non-volatile memory.

### BACKGROUND

In a memory system, in order to protect data to be stored in a memory such as a NAND flash memory, the data is subjected to error correction encoding and then is stored in the memory. For this reason, when the data stored in the memory is read, the error correction encoded data (also referred to as a received word) read from the memory is decoded to restore the data before the error correction encoding.

In a technique regarding an error correction code, the multiplication of a Galois field (finite field) may be performed. For example, in decoding a Bose-Chaudhuri-Hocquenghem (BCH) code, which is an example of the error correction code, a syndrome is calculated from a received word (read sequence) read from the memory, and a coefficient of an error locator polynomial is calculated from the syndrome. The syndrome is an element of the Galois field. For this reason, when the coefficient of the error locator polynomial is calculated, the multiplication of the syndrome, namely, the multiplication of the Galois field may be performed. In addition, in calculating the coefficient of the error locator polynomial, multiple times of multiplications of the Galois field may cause an increase in calculation time.

### BRIEF DESCRIPTION OF THE DRAWINGS

FIG. 1 is a block diagram of a memory system according to an embodiment;

FIG. 2 is a block diagram of a decoder according to the embodiment;

FIG. 3 is a diagram illustrating an outline of a calculation procedure of a syndrome and an error locator polynomial;

FIG. 4 is a diagram illustrating an example of the relationship between the syndrome and the error locator polynomial;

FIG. 5 is a diagram illustrating examples of vector representation of elements of a Galois field GF(2⁴);

FIG. 6 is a diagram for describing an example of a companion matrix;

FIG. 7 is a diagram illustrating an example of a method of obtaining a tensor Tⁱ;

FIG. 8 is a diagram illustrating a specific example of a method of obtaining a tensor T⁰;

FIG. 9 is a diagram illustrating an example of a method of obtaining a tensor S(1);

FIG. 10 is a diagram illustrating a specific example of a method of obtaining the tensor S(1);

FIG. 11 is a diagram illustrating a configuration example of an arithmetic unit;

FIG. 12 is a diagram illustrating a circuit configuration example in which the arithmetic unit of FIG. 11 is specified;

FIG. 13 is a diagram of a matrix in which six tensors each represented by a one-dimensional vector are arranged;

FIG. 14 is a diagram illustrating examples of diagram representation of tensors;

FIG. 15 is a diagram illustrating an example of diagram representation corresponding to direct product;

FIG. 16 is a diagram illustrating an example of diagram representation corresponding to contraction;

FIG. 17 is a diagram illustrating an example of diagram representation corresponding to contraction;

FIG. 18 is a diagram illustrating the relationship between an arithmetic unit in a comparative example and an arithmetic unit in the embodiment;

FIG. 19 is a diagram illustrating a circuit configuration example according to the embodiment, in which an arithmetic unit is specified;

FIG. 20 is a diagram illustrating an example of a flattened matrix;

FIG. 21 is a table for describing examples of reductions in the number of steps;

FIG. 22 is a diagram illustrating configuration examples of arithmetic units;

FIG. 23 is a diagram illustrating configuration examples of arithmetic units;

FIG. 24 is a diagram illustrating an example of an arithmetic unit;

FIG. 25 is a diagram illustrating a configuration example of an arithmetic unit that calculates an inverse element;

FIG. 26 is a diagram illustrating a configuration example of an arithmetic unit;

FIG. 27 is a diagram illustrating a configuration example of an arithmetic unit;

FIG. 28 is a diagram illustrating a configuration example of an arithmetic unit; and

FIG. 29 is a flowchart illustrating an example of decoding processing.

### DETAILED DESCRIPTION

According to an embodiment, arithmetic circuitry includes circuitry that is configured to perform a first arithmetic operation by AND operations and XOR operations. The first arithmetic operation corresponds to p multiplications (p is an integer of 2 or more) to be performed in series. The p multiplications are respectively represented by p order-3 tensors each receiving two elements of a Galois field as inputs and outputting one element as a result of multiplication of the two elements. The AND operation calculates an AND value of a plurality of elements used in the p multiplications. The XOR operation is based on a contracted tensor obtained by contraction of an order-3p tensor obtained by a direct product of the p order-3 tensors and the AND value.

Preferred embodiments of arithmetic circuitry according to the invention will be described in detail below with reference to the accompanying drawings.

Hereinafter, a memory system including arithmetic circuitry that performs the multiplication of a Galois field at the time of decoding of an error correction code will be described as an example. A configuration using the arithmetic circuitry is not limited to this example, and any system (apparatus or device) may be used. For example, the arithmetic circuitry described below can be also applied to a memory system that performs the multiplication of a Galois field at the time of calculation of an error position, a system that performs the multiplication of a Galois field at the time of cipher processing, and the like.

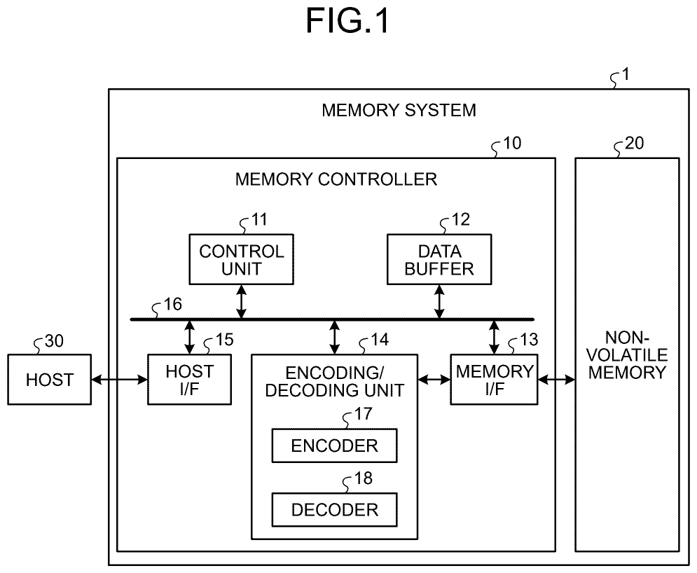

A memory system according to the present embodiment will be described in detail with reference to the drawings. FIG. 1 is a block diagram illustrating a schematic configuration example of the memory system according to the present embodiment. As illustrated in FIG. 1, a memory system 1 includes a memory controller 10 and a non-volatile memory 20. The memory system 1 can be connected to a host 30, and FIG. 1 illustrates the memory system 1 in connection with the host 30. The host 30 may be an electronic device, such as a personal computer or a mobile terminal.

The non-volatile memory 20 is a non-volatile memory that stores data in a non-volatile manner and is, for example, a NAND flash memory (hereinafter, simply referred to as a NAND memory). Although a case where a NAND memory is used as the non-volatile memory 20 will be exemplified in the following description, a storage device other than the NAND memory, such as a three-dimensional structure flash memory, a resistive random access memory (ReRAM), or a ferroelectric random access memory (FeRAM), can be used as the non-volatile memory 20. In addition, the non-volatile memory 20 is not necessarily a semiconductor memory, and thus the present embodiment can be also applied to various types of storage media other than the semiconductor memory.

The memory system 1 may be any type of memory system including the non-volatile memory 20, such as a so-called solid state drive (SSD) or a memory card in which the memory controller 10 and the non-volatile memory 20 are configured as a single package.

The memory controller 10 controls writing to the non-volatile memory 20 in accordance with a write request from the host 30. In addition, the memory controller 10 controls reading from the non-volatile memory 20 in accordance with a read request from the host 30. The memory controller 10 is, for example, a semiconductor integrated circuit configured as a system on a chip (SoC). The memory controller 10 includes a host interface (host I/F) 15, a memory interface (memory I/F) 13, a control unit 11, an encoding/decoding unit (CODEC) 14, and a data buffer 12. The host I/F 15, the memory I/F 13, the control unit 11, the encoding/decoding unit 14, and the data buffer 12 are mutually connected through an internal bus 16. Part or the entirety of the operation of each constituent element of the memory controller 10 described below may be implemented by execution of firmware by a central processing unit (CPU) or may be implemented by hardware.

The host I/F 15 serves as a circuit that performs processing pursuant to an interface standard with the host 30 and outputs a command, user data to be written, or the like received from the host 30 to the internal bus 16. In addition, the host I/F 15 transmits user data restored after reading from the non-volatile memory 20, a response from the control unit 11, or the like to the host 30.

The memory I/F 13 serves as a circuit that performs write processing to the non-volatile memory 20 based on an instruction from the control unit 11. In addition, the memory I/F 13 performs read processing from the non-volatile memory 20 in accordance with an instruction from the control unit 11.

The control unit 11 controls the constituent components of the memory system 1, integrally. In a case where a command is received from the host 30 through the host I/F 15, the control unit 11 performs control pursuant to the command. For example, in accordance with a command from the host 30, the control unit 11 instructs the memory I/F 13 to write user data and parity to the non-volatile memory 20. In addition, in accordance with a command from the host 30, the control unit 11 instructs the memory I/F 13 to read user data and parity from the non-volatile memory 20.

In addition, in a case where a write request is received from the host 30, the control unit 11 determines a storage area (memory area) on the non-volatile memory 20 for the user data accumulated in the data buffer 12. That is, the control unit 11 manages a write destination for the user data. The correspondence between the logical address of user data received from the host 30 and the physical address indicating the storage area in which the user data is stored on the non-volatile memory 20 is stored as an address conversion table.

In addition, in a case where a read request is received from the host 30, the control unit 11 converts the logical address designated by the read request into a physical address by using the above-described address conversion table and instructs the memory I/F 13 to perform reading from the physical address.

In general, in a NAND memory, writing and reading are performed in data units called pages and erasing is performed in data units called blocks. In the present embodiment, a plurality of memory cells connected to the same word line is referred to as a memory cell group. In a case where each memory cell is a single level cell (SLC), one memory cell group corresponds to one page. In a case where each memory cell is multiple level cell (MLC), one memory cell group corresponds to multiple pages. Note that, in the present description, examples of the MLC include a triple level cell (TLC) and a quad level cell (QLC). Each memory cell is connected to a word line and is also connected to a bit line. Therefore, each memory cell can be identified by an address for identifying the word line and an address for identifying the bit line.

The data buffer 12 temporarily stores the user data received from the host 30 by the memory controller 10 until the user data is stored into the non-volatile memory 20. In addition, the data buffer 12 temporarily stores the user data read from the non-volatile memory 20 until the user data is transmitted to the host 30. For the data buffer 12, a general-purpose memory, such as a static random access memory (SRAM) or a dynamic random access memory (DRAM), can be used. Note that the data buffer 12 may be mounted outside the memory controller 10 instead of being built in the memory controller 10.

The user data transmitted from the host 30 is transferred to the internal bus 16 and then is temporarily stored in the data buffer 12. The encoding/decoding unit 14 encodes the user data to be stored in the non-volatile memory 20 to generate a code word. In addition, the encoding/decoding unit 14 decodes the received word read from the non-volatile memory 20 to restore the user data. Therefore, the encoding/decoding unit 14 includes an encoder 17 and a decoder 18. Note that data to be encoded by the encoding/decoding unit 14 may include, for example, control data for use inside the memory controller 10 in addition to the user data.

Next, write processing in the present embodiment will be described. At the time of writing to the non-volatile memory 20, the control unit 11 instructs the encoder 17 to encode user data. At that time, the control unit 11 determines a storage location (storage address) for a code word in the non-volatile memory 20 and also instructs the memory I/F 13 on the determined storage location.

The encoder 17 encodes the user data on the data buffer 12 to generate a code word in accordance with on the instruction from the control unit 11. Examples of an encoding method include: an encoding method using an algebraic code, such as a Bose-Chaudhuri-Hocquenghem (BCH) code or a Reed-Solomon (RS) code, and an encoding method (e.g., a product code) using the BCH code and the RS code as component codes in a row direction and a column direction. The memory I/F 13 performs control to store the code word in the storage location on the non-volatile memory 20 instructed from the control unit 11. Hereinafter, a case where a BCH code is used for correcting an error of t bits or less (t is an integer of 2 or more) will be described as an example.

Next, processing at the time of reading from the non-volatile memory 20 in the present embodiment will be described. At the time of reading from the non-volatile memory 20, the control unit 11 designates an address on the non-volatile memory 20 and instructs the memory I/F 13 to perform reading. In addition, the control unit 11 instructs the decoder 18 to start decoding. In accordance with the instruction from the control unit 11 the memory I/F 13 reads a received word from the designated address of the non-volatile memory 20 and inputs the read received word to the decoder 18. The decoder 18 decodes the received word read from the non-volatile memory 20.

The decoder 18 decodes the received word read from the non-volatile memory 20. The decoder 18 performs calculation of an error locator polynomial by using, for example, the Peterson Gorenstein Zierler (PGZ) algorithm. The PGZ algorithm is a method of solving, by matrix calculation, a system of equations between coefficients σ of an error locator polynomial and the syndrome of a received word.

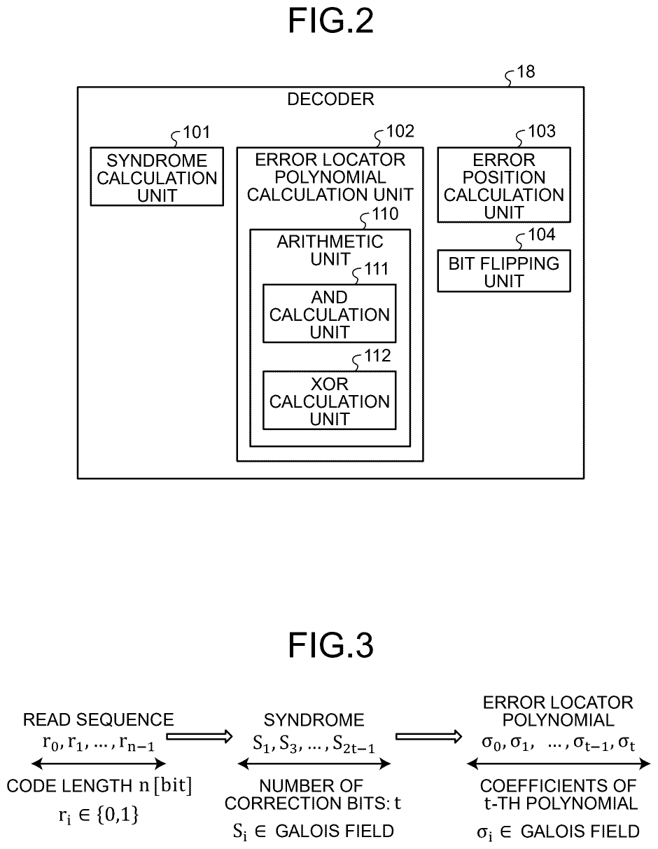

FIG. 2 is a block diagram illustrating a configuration example of the decoder 18 according to the present embodiment. As illustrated in FIG. 2, the decoder 18 includes a syndrome calculation unit 101, an error locator polynomial calculation unit 102, an error position calculation unit 103, and a bit flipping unit 104.

The syndrome calculation unit 101 calculates a syndrome by using a received word (read sequence) read from the non-volatile memory 20. The syndrome calculation unit 101 may calculate a syndrome based on any conventionally available method. In a case where the values of all syndromes are zero, it can be determined that the received word has no error and thus the decoder 18 can end the decoding processing without performing the subsequent processing.

The error locator polynomial calculation unit 102 calculates an error locator polynomial based on the PGZ algorithm by using the syndrome. Some of the coefficients of such an error locator polynomial are calculated by performing the addition of syndromes and the multiplication of syndromes.

FIG. 3 is a diagram illustrating an outline of a calculation procedure of a syndrome and an error locator polynomial with a BCH code. A read sequence r₀, r₁, r₂, . . . , rₙ₋₁ having a code length of n bits is read as received words from the non-volatile memory 20. The syndrome calculation unit 101 receives the received words as inputs to calculate syndromes S₁, S₃, . . . , and S₂ₜ₋₁. The error locator polynomial calculation unit 102 calculates coefficients σ₀, σ₁, . . . , σₜ₋₁, and σₜ of a t-th-degree error locator polynomial from the syndromes. As illustrated in FIG. 3, the syndromes and the coefficients σ calculated by using the syndromes are elements of a Galois field.

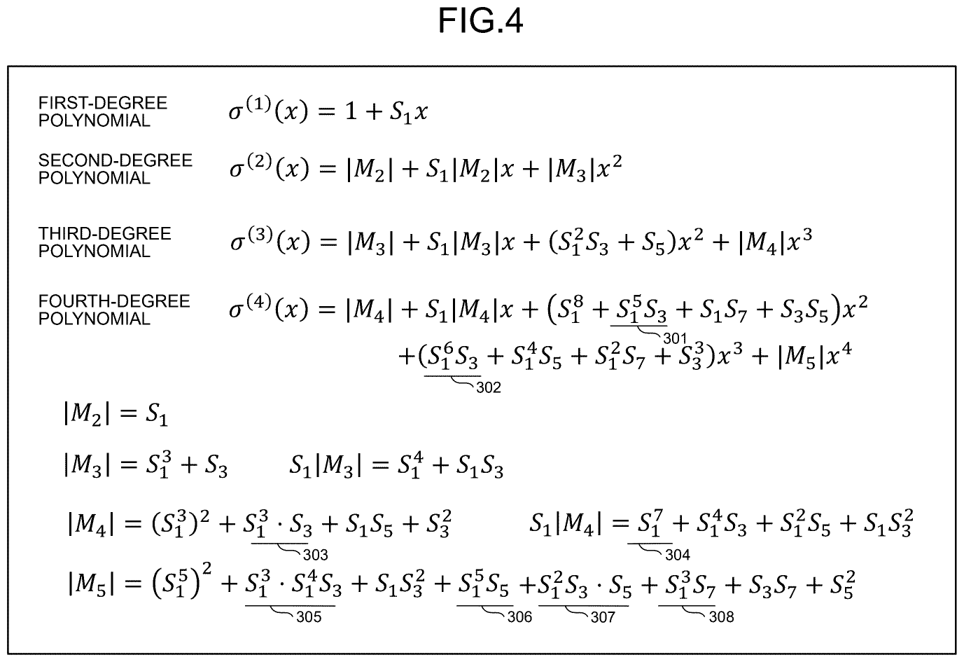

FIG. 4 is a diagram illustrating an example of the relationship between a syndrome and an error locator polynomial. Note that FIG. 4 illustrates an example of first-degree to fourth-degree error locator polynomials (first-degree polynomial to fourth-degree polynomial) in a case where a BCH code is used for correcting an error of 4 bits or less (t=4). |M₂|, |M₃|, |M₄|, and |M₅| included in any of the second-degree polynomial to the fourth-degree polynomial are each calculated by the corresponding formula illustrated in the lower part of FIG. 4.

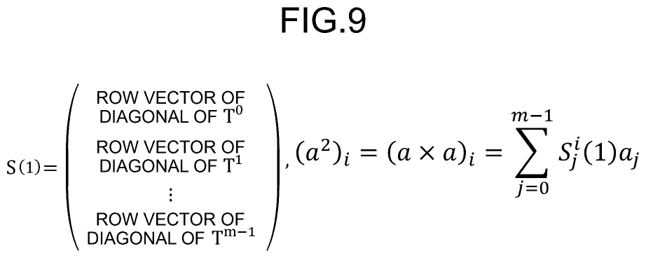

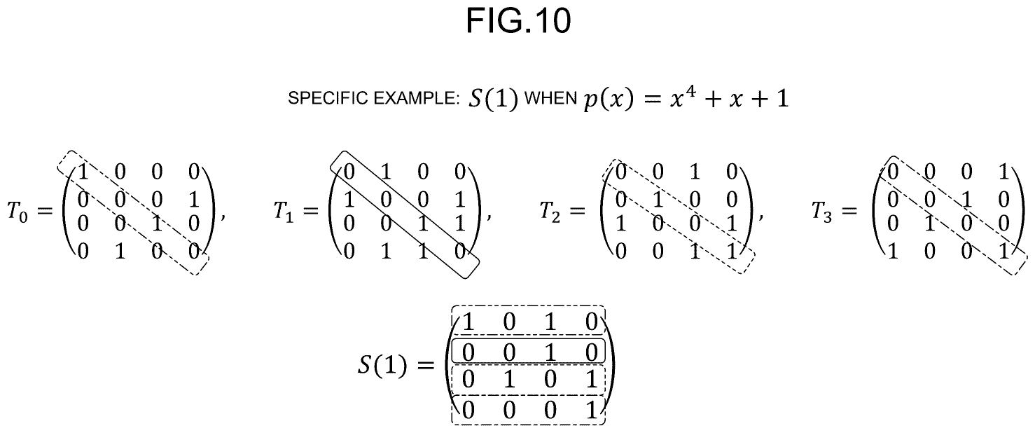

The first-degree to fourth-degree polynomials are formulas for error position calculation in a case where the numbers of errors are one to four, respectively. In the example of FIG. 4, the numbers of multipliers required for calculating coefficients of the first-degree polynomial to the fourth-degree polynomial are, for example, 0, 1, 5, and 21, respectively, except for the second power that can be implemented by simple calculation described with reference to FIGS. 9 and 10. Thus, as the number of error-correctable bits t increases, the number of multipliers for coefficient calculation of an error locator polynomial increases.

Therefore, a technique using an optimized arithmetic circuitry has been proposed. Such an optimized arithmetic circuitry is capable of performing shared computation of at least some of multiplication of syndromes used in coefficient calculation of an error locator polynomial. This enables suppression of an increase in the circuit size for performing the multiplication of a Galois field. This technique corresponds to a technique for commonly calculating a single multiplication that is included in common in plural types of multiplication. In one example, arithmetic circuitry is configured to calculate the multiplication S₁S₃ that is included in common in each of S₁²S₃, S₁S₃, S₁⁴S₃, and S₁S₃², which are four types of multiplication.

Meanwhile, the coefficient calculation of an error locator polynomial may include multiple times of multiplication to be performed in series (hereinafter, referred to as multiple steps of multiplication). Multiple times of multiplication to be performed in series refer to multiplication in which an output from a certain multiplication included in the multiple times of multiplication serves as an input to another multiplication. Referring to FIG. 4, multiplications 301 to 308 each correspond to an arithmetic operation that can be interpreted as including multiple steps of multiplication. The multiplication 301 can be interpreted as a calculation including two steps of multiplication as in S₁⁵S₃=S₁×S₁⁴×S₃. An increase in the number of steps of multiplication may cause an increase in calculation time. For this reason, desirably, multiple steps of multiplication are calculated more efficiently.

Therefore, an arithmetic unit 110 in the present embodiment is configured to efficiently perform an arithmetic operation including multiple steps of multiplication. Hereinafter, an example in which the arithmetic unit 110 is configured to calculate the multiplication 304 that is the seventh power of the syndrome S₁ will be mainly described. The arithmetic unit 110 may be configured to calculate another multiplication (for example, any of the multiplications 301 to 303 and the multiplications 305 to 308) or may be configured to calculate two or more multiplications (for example, any two or more of the multiplications 301 to 308).

Referring back to FIG. 2, the arithmetic unit 110 (an example of arithmetic circuitry) will be further described. As illustrated in FIG. 2, the error locator polynomial calculation unit 102 includes the arithmetic unit 110 that performs an arithmetic operation of elements of a Galois field including the multiplication of elements of the Galois field. The arithmetic unit 110 includes an AND calculation unit 111 and an XOR calculation unit 112.

The AND calculation unit 111 performs AND operations to perform the multiplication of elements of the Galois field. The XOR calculation unit 112 performs XOR operations to perform the multiplication of elements of the Galois field. Details of the AND calculation unit 111 and the XOR calculation unit 112 will be described later.

Note that the arithmetic unit 110 serves as a constituent unit that performs at least part of the multiplication of syndromes required for coefficient calculation of an error locator polynomial. Any multiplication of syndromes that the arithmetic unit 110 does not perform is calculated by, for example, the error locator polynomial calculation unit 102. In this case, the error locator polynomial calculation unit 102 may perform coefficient calculation (including the multiplication of syndromes) based on any conventionally available method.

The error position calculation unit 103 calculates an error position by using the error locator polynomial calculated by the error locator polynomial calculation unit 102. Although processing for calculating an error position (search processing) may be implemented by any method, for example, Chien search can be used. The Chien search is a method of sequentially substituting a value into an error locator polynomial and searching for an error position based on the value at which the error locator polynomial has an output value of 0.

The bit flipping unit 104 inverts the bit at the error position calculated by the search processing (bit flipping) to perform error correction.

Next, details of the arithmetic unit 110 (AND calculation unit 111 and XOR calculation unit 112) will be described. The arithmetic unit 110 is configured based on the following procedure, for example.
(P1) Determine m defining the number of elements 2^{m} of a Galois field and a primitive polynomial p(x) with a degree of m. Note that, instead of such a primitive polynomial, an irreducible polynomial may be used.
(P2) Obtain a companion matrix corresponding to the primitive polynomial p(x).
(P3) Obtain a plurality of tensors to be used in the multiplication of elements of the Galois field, by using the companion matrix. When an element of the Galois field is represented by an m-dimensional vector, an element that is an output obtained by multiplying two elements is also represented by an m-dimensional vector. A tensor is obtained for each component of an element as an output represented by an m-dimensional vector. Thus, m tensors, each of which is a function that receives two vectors as inputs and outputs one value (one component of a vector) as an output, are obtained in total. Hereinafter, a tensor defined for the i-th component of an m-dimensional vector is represented as Tⁱ (i is an integer satisfying 0≤i≤m−1). The tensor Tⁱ may be referred to as an order-2 tensor because the number of input vectors is two. In addition, the entirety of m order-2 tensors is characterized by three indices and thus may be referred to as an order-3 tensor.
(P4) Obtain an order-2 tensor S(u) representing the 2^{u}-th power of an element of the Galois field (u is an integer of one or more).
(P5) For an arithmetic operation including multiple steps of multiplication to be performed by the arithmetic unit 110, rewrite a plurality of sets of XOR operations segmented by AND operations to a single set of XOR operations. Specifically, an arithmetic operation by the arithmetic unit 110 is represented by AND operations of m-dimensional vectors and XOR operations represented by a tensor obtained by direct product and contraction.
(P6) Configure the arithmetic unit 110 to perform XOR operations pursuant to the tensor.

Each of the above procedures will be further described below.

Regarding (P1), the definition of a Galois field will be described. The Galois field is determined by m∈{1, 2, 3 . . . } defining the number of elements and a primitive polynomial p(x) with a degree of m. The Galois field has the following characteristics.
The Galois field has 2^{m} elements consisting of one zero element 0 and (2^{m}−1) non-zero elements.
A non-zero element can be represented by the power of a primitive element a that is the root of the primitive polynomial p(x) as in the following Formula (1).

$$GF ( {2}^{m} ) := \{ 0 , {α}^{0} ( = 1 ) , {α}^{1} , {α}^{2} , ... , {α}^{{2}^{m} - 2} \} , p ( x = α ) = 0 \qquad ( 1 )$$

In a BCH code having a code length n=2^{m}−1 (m is an integer of 2 or more), a Galois field GF(2^{m}) having 2^{m} elements may be used. The Galois field GF(2^{m}) has an element that can be represented by an m-bit vector (m-dimensional vector).

An element a € GF(2^{m}) of the Galois field GF(2^{m}) can be represented by a polynomial on GF(2) having a degree of (m−1) with respect to the primitive element a as in the following Formula (2). Note that i is an integer satisfying 0≤i≤m−1.

$$a = {a}_{0} {α}^{0} + {a}_{1} {α}^{1} + {a}_{2} {α}^{2} + … + {a}_{m - 1} {α}^{m - 1} , {a}_{i} ∈ \{ 0 , 1 \} = GF ( 2 ) \qquad ( 2 )$$

Therefore, the element a can be represented by an m-dimensional vector on GF(2) having the coefficients of a polynomial on GF(2) as components, as shown in the following Formula (3).

$$\vec{a} = ( {a}_{0} , {a}_{1} , {a}_{2} , ... , {a}_{m - 1} ) \qquad ( 3 )$$

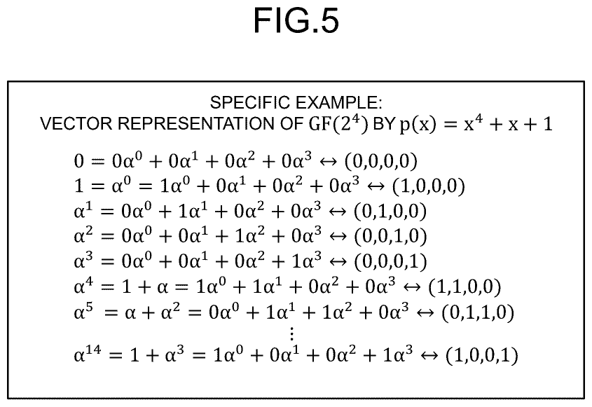

For example, a Galois field GF(2¹⁰) used in a BCH code having a code length of n=210-1 has an element that can be represented by a 10-bit vector. In addition, a Galois field GF(2⁴) used in a BCH code having a code length of n=24-1 has an element that can be represented by a 4-bit vector. FIG. 5 is a diagram illustrating examples of vector representation of elements of the Galois field GF(2⁴) in which the primitive polynomial is represented by p(x)=x⁴+x+1 with m=4.

An element 0 is represented by a polynomial 0α⁰+0α¹+0α²+0α³ and is represented by a four-dimensional vector (0, 0, 0, 0) having the coefficients of the polynomial as components. Since a primitive element a satisfies a primitive polynomial p(α)=α⁴+α+1=0, in other words, satisfies α⁴=α+1, an element α⁴ can be transformed into 1+α. Therefore, the element α⁴ is represented by a polynomial 1α⁰+1α¹+0α²+0α³ and is represented by a four-dimensional vector (1, 1, 0, 0) having the coefficients of the polynomial as components.

In addition, the addition of elements of the Galois field is represented by the XOR of two vectors for each bit. In the present embodiment, the multiplication of elements of the Galois field is performed by circuitry as an arithmetic circuitry in which AND operations and XOR operations are in combination.

In (P1), m defining the number of elements of a Galois field to be subjected to an arithmetic operation is determined. The value of m may be determined in any manner and thus may be determined in accordance with, for example, an encoding method to be applied or a type of memory to be applied. In a case where the memory system 1 uses a BCH code having a code length of 1000 bits, m is determined to be 10 such that the number of elements (2¹⁰=1024>1000) larger than the code length is included. In the Galois field, one or more primitive polynomials are defined for each value of m. Among the primitive polynomials, one primitive polynomial to be used is determined.

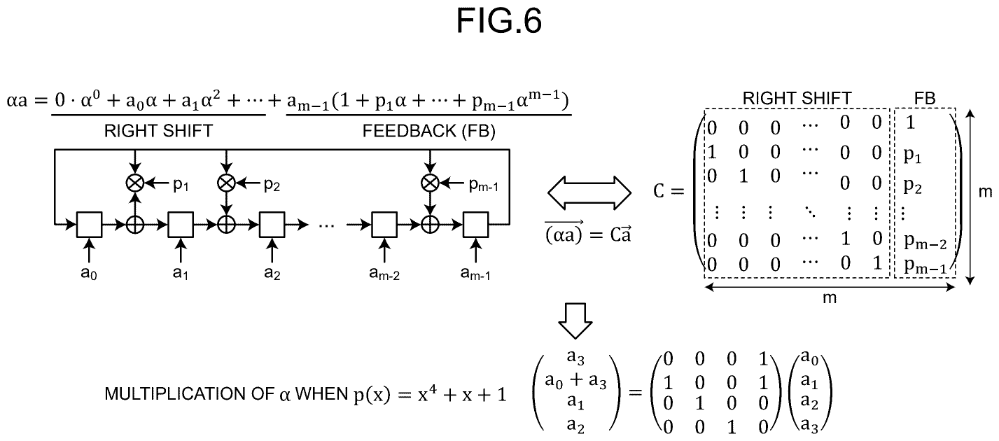

Next, (P2) will be described. Upon determining a primitive polynomial p(x), a matrix called a companion matrix is determined. FIG. 6 is a diagram for describing an example of the companion matrix.

The multiplication of an element a and a primitive element α of the Galois field can be represented by the multiplication of a companion matrix C and a vector representing the element a. The multiplication with the primitive element a can be divided into an arithmetic operation corresponding to right shift and an arithmetic operation corresponding to feedback (FB). The circuit in FIG. 6 illustrates an example of a circuit corresponding to such right shift and feedback. The feedback can be interpreted as processing for a term that overflows due to the right shift. The companion matrix C can be also divided into a column corresponding to the right shift (first column to (m−1)-th column) and a column corresponding to the feedback (m-th column).

The multiplication of a in the Galois field GF(2⁴) in which the primitive polynomial is represented by p(x)=x⁴+x+1 can be represented by the multiplication of the companion matrix C and the element a as shown in the formula in the lower part of FIG. 6. In the procedure (P2), the companion matrix corresponding to the determined primitive polynomial is obtained in this manner.

Next, (P3) will be described. In (P3), m tensors Tⁱ for use in the multiplication of elements of the Galois field are obtained by using the companion matrix. When m=10, ten tensors T⁰ to T⁹ are obtained.

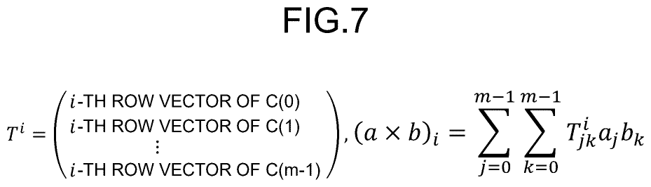

FIG. 7 is a diagram illustrating an example of a method of obtaining the tensor Tⁱ. As illustrated in FIG. 7, the tensor Tⁱ is obtained by arranging the respective i-th row vectors of matrices C(0) to C(m−1). Note that a matrix C(p) means the p-th power of the companion matrix C(p is an integer satisfying 0≤p≤m−1).

FIG. 7 also illustrates an example of a formula indicating the relationship between the tensor Tⁱ and the multiplication of elements a and b of the Galois field. (a×b)ᵢ represents the i-th bit of a m-bit vector indicating a result of the multiplication of the elements a and b. As illustrated in FIG. 7, (a×b)ᵢ can be represented by the multiplication of a vector indicating the element a, a vector indicating the element b, and the tensor Tⁱ. In addition, (a×b)ᵢ can be represented in the form of the sum of AND operations of the j-th component aⱼ of a (j is an integer satisfying 0≤j≤m−1) and the k-th component bx of b (k is an integer satisfying 0≤k≤m−1).

As illustrated in FIG. 7, the tensor Tⁱ for use in the multiplication of the elements a and b can be represented by a combination of aⱼbₖ being an AND operation and XOR operations (ΣTⱼₖⁱ) corresponding to the sum of results of the AND operations. Note that the tensor Tⱼₖⁱ represents a tensor corresponding to an XOR operation. The subscripts j and k of the tensor Tⱼₖⁱ correspond, respectively, to the indices of the elements a and b, which are vectors as inputs to the XOR operation (input vectors). The superscript i of the tensor Tⱼₖⁱ corresponds to the index of a×b, which is a vector as an output from the XOR operation (output vector). Note that the tensor Tⱼₖⁱ may be referred to as a circular convolution tensor. The tensor Tⱼₖⁱ (circular convolution tensor) corresponds to an order-3 tensor that receives two elements of the Galois field as inputs (for example, the elements a and b) and outputs one element as a result of multiplication of the two elements (for example, an element ab).

Hereinafter, similarly, the subscript and superscript of a tensor corresponding to an arithmetic operation may be represented, respectively, by the index of the input vector to the arithmetic operation and the index of the output vector from the arithmetic operation. For example, in a case where the element a, which is an m-dimensional vector, has an index j and an element a², which is an m-dimensional vector, has an index i, a tensor S(1) representing the second power of the element a can be represented as Sⱼⁱ(1). Note that a vector that is an order-1 tensor has a component represented by a subscript. For example, the i-th component of the element a, which is an m-dimensional vector, is represented by aᵢ.

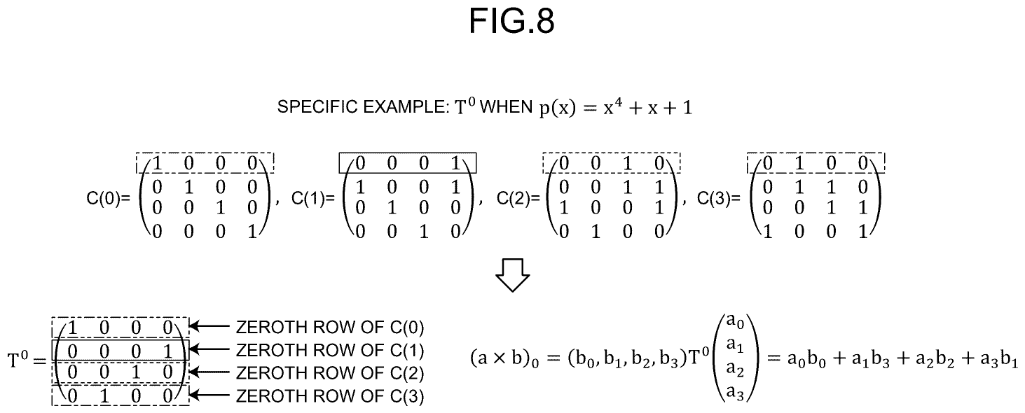

FIG. 8 is a diagram illustrating a specific example of a method of obtaining a tensor T⁰ in the case of m=4 and the primitive polynomial p(x)=x⁴+x+1. First, matrices C(0) to C(3) are obtained from the companion matrix C. The tensor T⁰ is obtained by arranging the respective zeroth rows of the matrices C(0) to C(3). In a case of using the tensor T⁰, (a×b)₀ is represented as a₀b₀+a₁b₃+a₂b₂+a₃b₁. Similarly, tensors T¹, T², and T³ can be obtained.

Next, (P4) will be described. The tensor S(1) representing the second power of an element of the Galois field can be obtained from the tensor Tⁱ. FIG. 9 is a diagram illustrating an example of a method of obtaining the tensor S(1). As illustrated in FIG. 9, the tensor S(1) is obtained by setting the main diagonal of the tensor Tⁱ as the i-th row vector.

FIG. 9 also illustrates an example of a formula indicating the relationship between the tensor S(1) and the second power of the element a of the Galois field (multiplication of the element a and the element a). As illustrated in FIG. 9, the second power (a×a) of the element a can be represented by the multiplication of a vector indicating the element a and the tensor S(1).

FIG. 10 is a diagram illustrating a specific example of a method of obtaining the tensor S(1) in the case of m=4 and the primitive polynomial p(x)=x⁴+x+1. The tensor S(1) is obtained by arranging respective diagonal components of the tensors T⁰ to T³. In a case of using the tensor S(1), a²(=a×a) is calculated as a vector (a₀+a₂, a₂, a₁+a₃, a₃).

The reason why only the diagonal components are extracted is that the components symmetrical with respect to the main diagonal are canceled to result in zero. For example, (a×a)₀ corresponding to the tensor T⁰ is a₀a₀+a₂a₂+a₃a₁+a₁a₃. In GF(2), the second power a² of the element a is equal to a, and the addition (a+a) of the same element a is zero. For example, a₀a₀ and a₂a₂ are a₀ and a₂, respectively. In addition, a₃a₁+a₁a₃ is zero because of the addition of the same element. Therefore, a₀a₀+a₂a₂+a₃a₁+a₁a₃ is represented as a₀+a₂.

The order-2 tensor S(u) representing the 2^{u}-th power of an element of the Galois field in a case where u is 2 or more can be obtained by raising S(1) obtained as described above to the u-th power. For example, an order-2 tensor S(2) representing the fourth power of an element of the Galois field is obtained by the calculation S(1)×S(1).

Next, (P5) will be described. Hereinafter, a configuration example of an arithmetic unit that calculates the seventh power of a of the Galois field (a⁷) will be described.

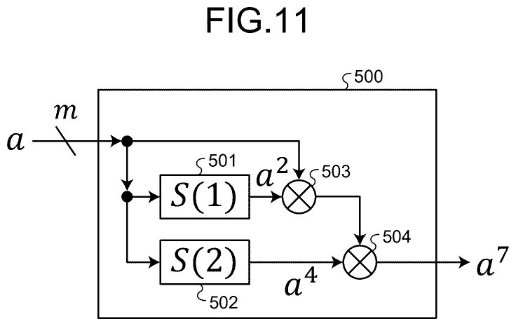

FIG. 11 is a diagram illustrating a configuration example of an arithmetic unit 500 that calculates the seventh power of a of the Galois field (a⁷). The arithmetic unit 500 includes XOR calculation units 501 and 502 and multiplication units 503 and 504.

The XOR calculation unit 501 performs XOR operations corresponding to the second power of the Galois field. As described above, an order-2 tensor representing the second power of an element of the Galois field is represented by S(1). The XOR calculation unit 501 performs XOR operations corresponding to the tensor S(1) to calculate a² that is the second power of the input element a.

The XOR calculation unit 502 performs XOR operations corresponding to the fourth power of the Galois field. As described above, an order-2 tensor representing the fourth power of an element of the Galois field is represented by S(2). The XOR calculation unit 502 performs XOR operations corresponding to the tensor S(2) to calculate a⁴ that is the fourth power of the input element a.

The multiplication unit 503 performs multiplication of the input element a and a² output from the XOR calculation unit 501 to output a³ resulting from the multiplication.

The multiplication unit 504 performs multiplication of a³ output from the multiplication unit 503 and a⁴ output from the XOR calculation unit 502 to output a⁷ resulting from the multiplication.

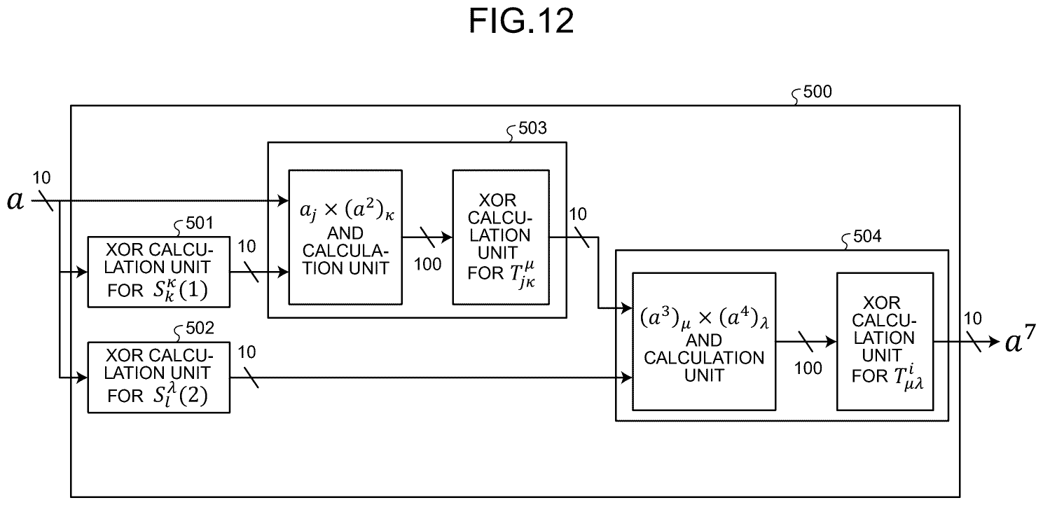

FIG. 12 is a diagram illustrating a circuit configuration example of the arithmetic unit 500 in which the constituent elements are specified as a logic circuit. Unlike that of the present embodiment, as a configuration example, two XOR calculation units are separate by an AND calculation unit. Note that FIG. 12 illustrates a configuration example of the arithmetic unit 500 with m=10.

As described above, the multiplication of elements of the Galois field is represented by a combination of AND operations and XOR operations. For example, the multiplication unit 503 that performs the multiplication of the element a and the element a² is represented by an AND calculation unit based on an element aⱼ and an element (a²)_{κ} and an XOR calculation unit corresponding to a tensor T_{jκ}^{μ}. The multiplication unit 504 that performs the multiplication of the element a³ and the element a⁴ is represented by an AND calculation unit based on an element (a³) u and an element (a⁴), and an XOR calculation unit corresponding to a tensor T_{μλ}ⁱ. Note that, in the example of FIG. 12, i, j, k, l, κ, μ, and λ are each an integer of 0 or more and 9 or less.

Here, the computational complexity (calculation time) of the arithmetic unit 500 in a comparative example as in FIG. 12 will be described. First, the transformation of representation of a tensor for use in an arithmetic operation will be described.

In general, the tensor Tⱼₖⁱ can be represented by transformation to a one-dimensional vector with a plurality of indices j and k of input vectors in combination. The processing of transforming a tensor into a one-dimensional vector is referred to as flatten. In addition, a matrix obtained by flatten is referred to as a flattened matrix. The flattened matrix corresponds to a matrix in which one-dimensional vectors, in which a plurality of indices corresponding to a plurality of inputs is combined, are arranged and the number of one-dimensional vectors is identical to the number of elements of an index corresponding to one output. Hereinafter, a case where a Galois field GF(26) is used in which the primitive polynomial is represented by p(x)=x⁶+x+1 with m=6 will be described as an example.

The multiplication of an element a and an element b is represented by using an order-3 tensor Tⱼₖⁱ as in the following Formula (4). The zeroth element (i=0) in an output vector is calculated by an order-2 tensor Tⱼₖ⁰ represented by the following Formula (5).

$${( ab )}_{i} = {\sum }_{j , k} {T}_{jk}^{i} {a}_{j} {b}_{k} \qquad ( 4 )$$

$${T}_{jk}^{0} = ( \begin{matrix}1 & 0 & 0 & 0 & 0 & 0 \\ 0 & 0 & 0 & 0 & 0 & 1 \\ 0 & 0 & 0 & 0 & 1 & 0 \\ 0 & 0 & 0 & 1 & 0 & 0 \\ 0 & 0 & 1 & 0 & 0 & 0 \\ 0 & 1 & 0 & 0 & 0 & 0\end{matrix} ) \qquad ( 5 )$$

The tensor Tⱼₖ⁰ in Formula (5) can be transformed into a one-dimensional vector (1, 0, 0, 0, 0, 0, 0, 0, 0, 0, 0, 1, 0, 0, 0, 0, 1, 0, 0, 0, 0, 1, 0, 0, 0, 0, 1, 0, 0, 0, 0, 1, 0, 0, 0, 0) by coupling each row. The component at the j-th row and the k-th column of Tⱼₖ⁰ corresponds to the component at the q-th column of the one-dimensional vector (q=j+6k: q is an integer satisfying 0≤q≤35). In a similar procedure, the other tensors Tⱼₖ¹ to Tⱼₖ⁵ can be each transformed into a one-dimensional vector.

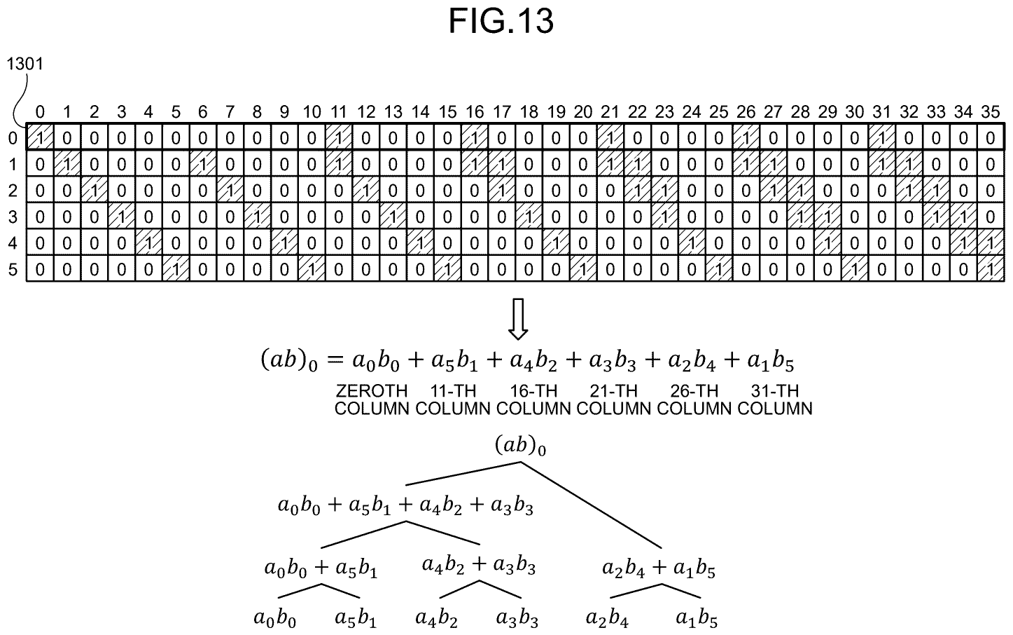

FIG. 13 is a diagram illustrating an example of a matrix in which six tensors Tⱼₖ⁰ to Tⱼₖ⁵ each represented by a one-dimensional vector are arranged (order-2 tensor). A vector 1301 is a one-dimensional vector corresponding to the tensor Tⱼₖ⁰.

A component having a value of 1 indicates that aⱼbₖ, which is the value of the corresponding AND operation, is used in XOR operations. Hereinafter, use in XOR operations may be referred to as contribution to XOR operations. In the example of Formula (5), the zeroth element in an output vector (ab)₀ is represented by (ab)₀=a₀b₀+a₅b₁+a₄b₂+a₃b₃+a₂b₄+a₁b₅. In this example, the number of terms for use in XOR operations (the number of terms contributing to XOR operations) is six.

In the present embodiment, as illustrated in the lower part of FIG. 13, based on a tree structure having terms as leaf nodes, XOR operations are performed in a tournament style. That is, first, three XOR operations are performed: a₀b₀+a₅b₁, a₄b₂+a₃b₃, and a₂b₄+a₁b₅. The respective results from the three XOR operations are defined as arithmetic results R01, R02, and R03. Next, an XOR operation is performed to the two arithmetic results R01 and R02 to output an arithmetic result R11. Finally, an XOR operation is performed to the arithmetic results R11 and R03 to output (ab)₀ as an arithmetic result.

In this example, the number of XOR operations to be performed in series for obtaining the final arithmetic result is three. Hereinafter, the number thereof is referred to as the number of stages of XOR operations (critical path). The number of stages ns of XOR operations is calculated based on ns=ceiling(log(the number of terms of XOR)). Ceiling(x) is a ceiling function that outputs a minimum integer of x or more. In the example of FIG. 13, the number of stages ns is as follows: ceiling(log(6))=3.

The computational complexity of the arithmetic unit 500 can be evaluated by such a number of steps as described above. The multiplication units 503 and 504 that perform multiplication account for most of the computational complexity of the arithmetic unit 500, and thus the computational complexity of the multiplication units 503 and 504 will be described.

The number of stages of the AND calculation unit in the multiplication unit 503 is one. With m=10, the number of terms in XOR operations of the XOR calculation unit ranges from 10 to 28. Because of ceiling(log(10))=4 and ceiling(log(28))=5, the number of stages of the XOR calculation unit in the multiplication unit 503 ranges from four to five. The number of stages of the entire multiplication unit 503 ranges from five to six. The number of stages of arithmetic operations of the multiplication unit 504 also ranges from five to six the same as the multiplication unit 503.

In the arithmetic unit 500 in the comparative example, the multiplication based on the multiplication unit 503 and the multiplication based on the multiplication unit 504 are performed in series. Therefore, the number of stages of arithmetic operations of the entire arithmetic unit 500 is 10 to 12 (two stages belonging to the AND calculation units and 8 to 10 stages belonging to the XOR calculation units). Since the multiplications to be performed in series are included, an increase in the number of stages of arithmetic operations may cause an increase in the calculation time of arithmetic operations of the entire arithmetic unit 500.

In the present embodiment, such multiple steps of multiplication as included in the arithmetic unit 500 are replaced with a single step of multiplication. Thus, the number of steps of entire arithmetic operation is suppressed, enabling higher-speed performance of multiple times of multiplication of the Galois field.
(P5) will be further described. In the present embodiment, by a procedure of tensor direct product and contraction, multiple steps of multiplication are replaced with a single step of multiplication. Terminology used for describing replacement of multiplication is described below.

In the present embodiment, a tensor T is defined as follows.
With a plurality of input vectors as inputs, transformation is provided such that linearity is established for each input (multilinearity). The linearity for each input is, for example, represented as follows.

$$T ( a + b , c ) = T ( a , c ) + T ( b , c )$$

$$T ( a , b + c ) = T ( a , b ) + T ( a , c )$$

The number of vectors related to transformation is called order.
The index of an input vector is arranged as a subscript and the index of an output vector is arranged as a superscript.

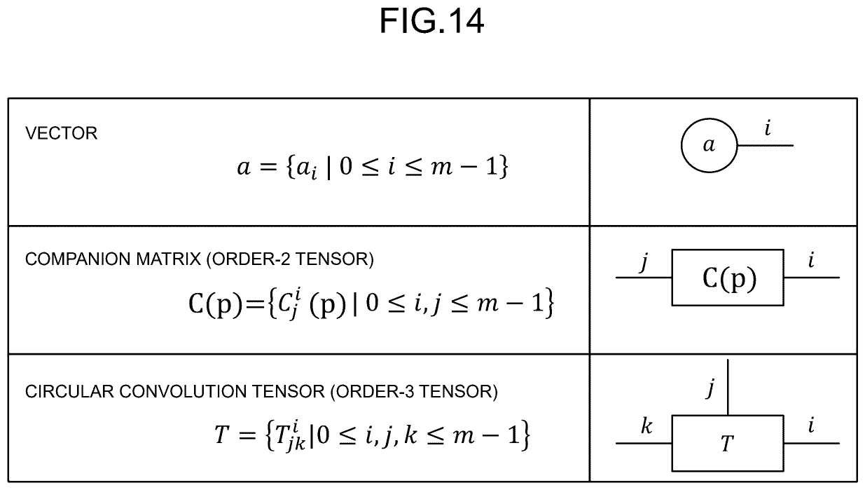

Moreover, hereinafter, an arithmetic operation of the Galois field may be represented as a network with a diagrammatically represented tensor (including a vector and a matrix). FIG. 14 is a diagram illustrating examples of diagram representation of tensors.

A vector a has a component aᵢ that is identified by a single index i. Therefore, the diagram representation of the vector a includes: a symbol a that is denoted inside a circle and represents a vector, and an undirected edge that outputs from the circle. The index i is added to the edge.

A companion matrix C that is an order-2 tensor has a component Cⱼⁱ identified by two indices i and j. The diagram representation of the companion matrix C includes: a symbol C that is denoted inside a rectangle and represents the companion matrix inside, an edge that is denoted with an index j and is input to the rectangle, and an edge that is denoted with an index i and is output from the rectangle.

A circular convolution tensor T that is an order-3 tensor has a component Tⱼₖⁱ identified by three indices i, j, and k. The diagram representation of the circular convolution tensor T includes: a symbol T that is denoted inside a rectangle and represents the circular convolution tensor inside, two edges that are denoted with indices j and k and are input to the rectangle, and an edge that is denoted with an index i and is output from the rectangle.

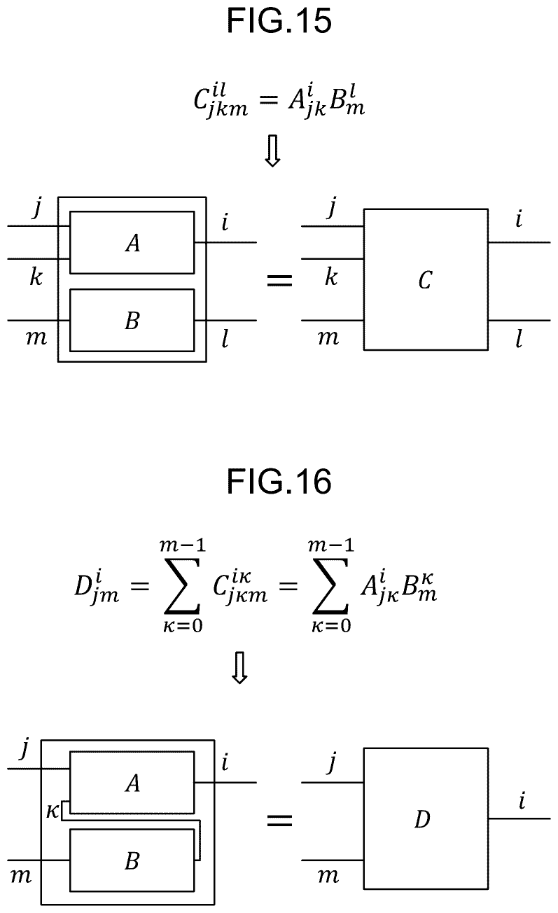

Next, tensor direct product will be described. The tensor direct product represents an operation to obtain a higher-order tensor having the product of respective components of two tensors. For example, a direct product of an order-3 tensor having Aⱼₖⁱ as a component and an order-2 tensor having Bₘ^{l} as a component corresponds to an operation to obtain an order-5 tensor having Cⱼₖₘ^{il}=AⱼₖⁱBₘ^{l} as a component. FIG. 15 is a diagram illustrating an example of diagram representation corresponding to this direct product.

Next, tensor contraction will be described. The tensor contraction represents an operation in which two different indices are selected and then are replaced with the same index to one tensor and then the sum is taken over the same index. For example, an operation in which two indices l and k are selected and then are replaced with the same index K to an order-5 tensor having Cⱼₖₘ^{il}=AⱼₖBₘ^{l} as a component and then the sum is taken over the index K to obtain an order-3 tensor Dⱼₘⁱ illustrated in the following Formula (6) corresponds to contraction. FIG. 16 is a diagram illustrating an example of diagram representation corresponding to this contraction.

$${D}_{jm}^{i} = {\sum }_{κ = 0}^{m - 1} {C}_{j κ m}^{i κ} = {\sum }_{κ = 0}^{m - 1} {A}_{j κ}^{i} {B}_{m}^{κ} \qquad ( 6 )$$

Here, the relationship between the multiplication of matrices (order-2 tensors) and the direct product and contraction will be described. A matrix S(2) obtained by multiplying two matrices (order-2 tensors) S(1) and S(1) is represented by the following Formula (7).

$$S ( 2 ) = {\sum }_{κ = 0}^{m - 1} {S}_{κ}^{i} ( 1 ) {S}_{j}^{κ} ( 1 ) \qquad ( 7 )$$

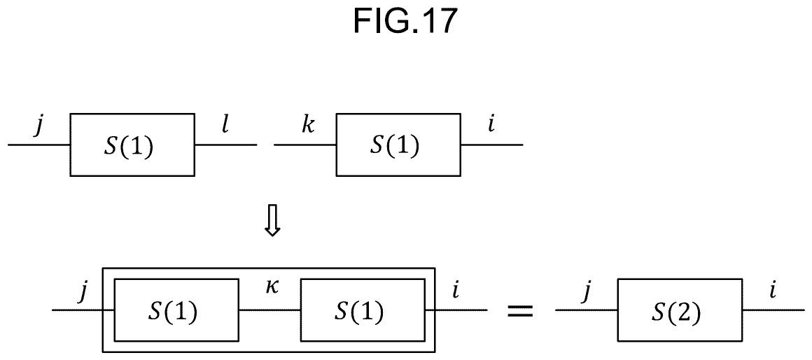

The matrix S(2) corresponds to a tensor (matrix) obtained by taking a direct product of the two matrices S(1) and S(1) and performing contraction by an index with an edge having its both endpoints in a region to be under a single operation. For example, an index K for linking the index 1 of an output from the first matrix Sⱼ^{l}(1) and the index k of an input to the second matrix Sₖⁱ(1) together is used for contracting the two matrices S(1) to a matrix Sⱼⁱ(2). FIG. 17 is a diagram illustrating an example of diagram representation corresponding to this contraction.

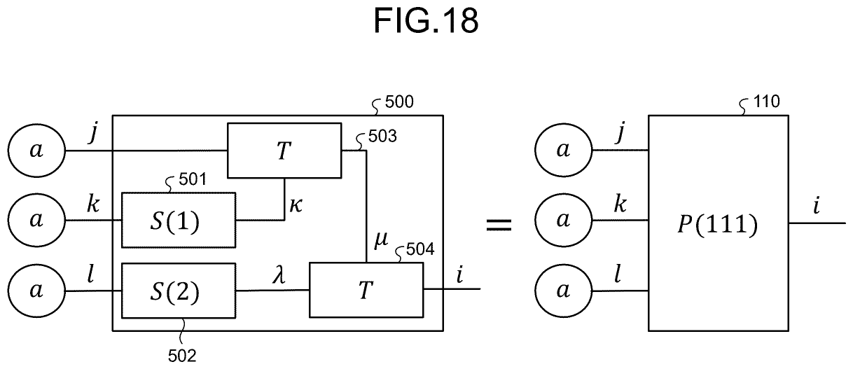

Next, an example in which direct product and contraction are applied to the arithmetic unit 500, in the comparative example, including two steps of multiplication to configure the arithmetic unit 110 in the embodiment will be described. FIG. 18 is a diagram illustrating the relationship between the arithmetic unit 500 and the arithmetic unit 110.

The arithmetic unit 500 illustrated in the left part of FIG. 18 has a configuration corresponding to, for example, a configuration in which the arithmetic operation of the arithmetic unit 500 in FIG. 12 is diagrammatically represented.

The arithmetic unit 500 is replaced with the arithmetic unit 110 illustrated in the right part of FIG. 18 due to direct product and contraction. The arithmetic unit 110 corresponds to a tensor P(111) representing the seventh power of an element a. Note that the “P” of the tensor P(111) represents power. “111” corresponds to the binary representation of “7” of the seventh power. The tensor P(111) is represented by the following Formula (8) by using the indices j, k, and l of inputs and the index i of an output.

$${P}_{jkl}^{i} ( 111 ) = {\sum }_{κ , λ , μ} {T}_{μλ}^{i} {T}_{j κ}^{μ} {S}_{k}^{κ} ( 1 ) {S}_{l}^{λ} ( 2 ) \qquad ( 8 )$$

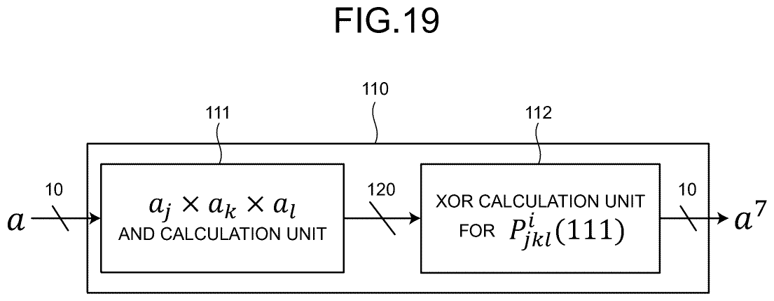

FIG. 19 is a diagram illustrating a circuit configuration example according to the embodiment, in which the arithmetic unit 110 is specified. Note that FIG. 19 illustrates a configuration example of the arithmetic unit 110 with m=10. The AND calculation unit 111 performs AND operations of elements aⱼ, aₖ, and aₗ. The XOR calculation unit 112 performs XOR operations corresponding to the tensor P(111).

Next, (P6) will be described. In (P6), the arithmetic unit 110 is configured (designed) to perform XOR operations pursuant to the tensor P(111). The configuration of the arithmetic unit 110 may be performed by any conventionally available method. For example, a method using a tool or the like that performs circuit design in a hardware description language at register transfer level (RTL) can be applied.

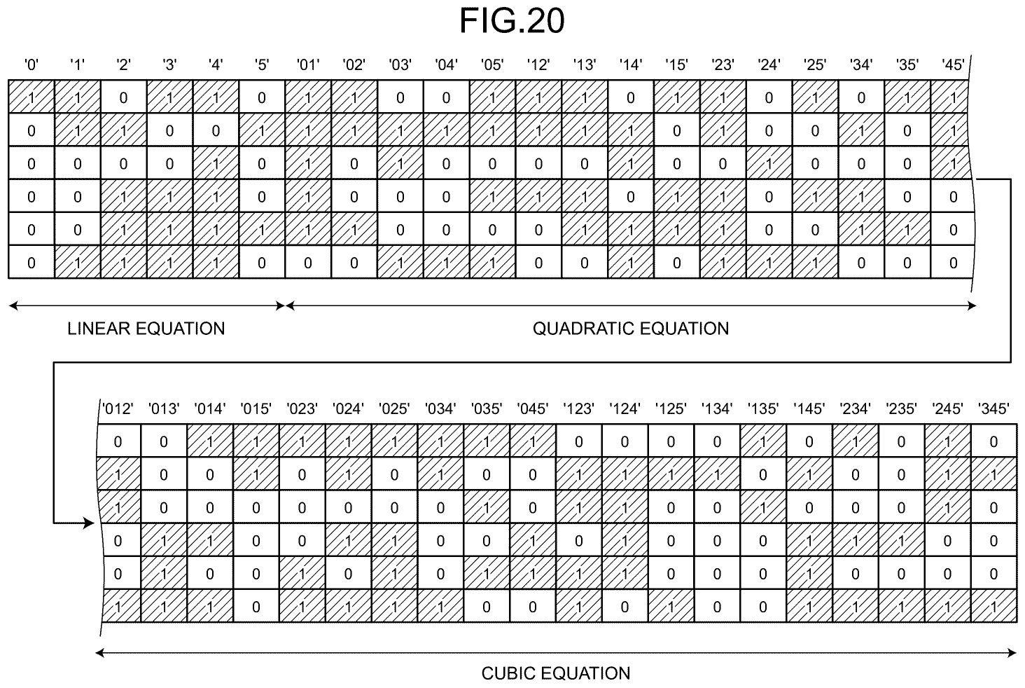

In (P6), the flatten of the tensor P(111) may be performed. FIG. 20 is a diagram illustrating an example of a flattened matrix obtained by flattening the tensor P(111). FIG. 20 illustrates an example of a flattened matrix of the tensor P(111) with m=6.

Since the tensor P(111) has three indices (j, k, l) for input and a single index (i) for output, a flattened matrix with simple flattening is a matrix of 6 rows and 63 columns. Meanwhile, three input vectors to the tensor P(111) are based on the same element a. For this reason, the flattened matrix can be simplified.

In a case where the indices (j, k, l) for input as a set are (2, 1, 1), a value for use in XOR operations is a₂×a₁×a₁. As described above, in GF(2), the second power a² of the element a is equal to a. Therefore, a₂×a₁×a₁ is equal to a₁×a₂. In addition, the contribution of a₂×a₁×a₁ to XOR operations is identical to the contribution of a₁×a₂. Similarly, regarding a set in which the value of any one index of (j, k, l) is “2” and the values of the other indices are “1” and a set in which the values of any two indices of (j, k, l) are “2” and the value of the other index is “1”, the contribution of each set to XOR operations is identical to the contribution of a₁×a₂. Thus, terms the same in terms of the contribution to XOR operations are collected into one and, in the case of even numbers of contributions, the contribution is brought into zero, so that the flattened matrix can be simplified.

FIG. 20 illustrates an example of a flattened matrix obtained by such simplification. Note that the flattened matrix in FIG. 20 corresponds to (a⁷)₀ to (a⁷)₅ as the output vector of the tensor P(111) represented as in the following Formula (9).

$$\begin{matrix}{( {a}^{7} )}_{0} = {a}_{0} + {a}_{1} + {a}_{3} + {a}_{4} + {a}_{0} {a}_{1} + {a}_{0} {a}_{2} + … + {a}_{2} {a}_{3} {a}_{4} + {a}_{2} {a}_{4} {a}_{5} \\ ⋮ \\ {( {a}^{7} )}_{5} = {a}_{1} + {a}_{2} + {a}_{3} + {a}_{4} + {a}_{0} {a}_{3} + {a}_{0} {a}_{4} + … + {a}_{2} {a}_{4} {a}_{5} + {a}_{3} {a}_{4} {a}_{5}\end{matrix} \} \qquad ( 9 )$$

Note that at least some of the above procedures (P1) to (P6) may be implemented by one or more processing units. Such processing units are implemented by one or more processors. The processing unit may be implemented by causing a processor, such as a central processing unit (CPU) or a graphics processing unit (GPU), to execute a program, namely, by software. The processing unit may be implemented by a processor such as a dedicated integrated circuit (IC), namely, by hardware. The processing unit may be implemented by software and hardware in combination. At least some of the procedures (P1) to (P6) may be implemented as the function of a tool used for the configuration of the arithmetic unit 110.

The computational complexity of the arithmetic unit 110 in the present embodiment will be described. The number of stages of the AND calculation unit 111 is two. With m=10, the number of terms in XOR operations by the XOR calculation unit 112 ranges from 79 to 92. Because of ceiling(log(79))=7 and ceiling(log(92))=7, the number of stages of the XOR calculation unit 112 is seven. The number of stages of the entire arithmetic unit 110 is nine.

Thus, in the present embodiment, the arithmetic unit 110 is configured such that a plurality of XOR calculation units is made compact together (in the example of FIG. 12, the respective XOR calculation units included in the multiplication units 503 and 504 and additionally the XOR calculation units 501 and 502). Thus, for example, in comparison to the arithmetic unit 500, of which the number of stages ranges from 10 to 12, in the comparative example, the number of stages of arithmetic operation of the arithmetic unit 110 can be suppressed to nine. That is, multiple times of multiplication of the Galois field can be performed at higher speed.

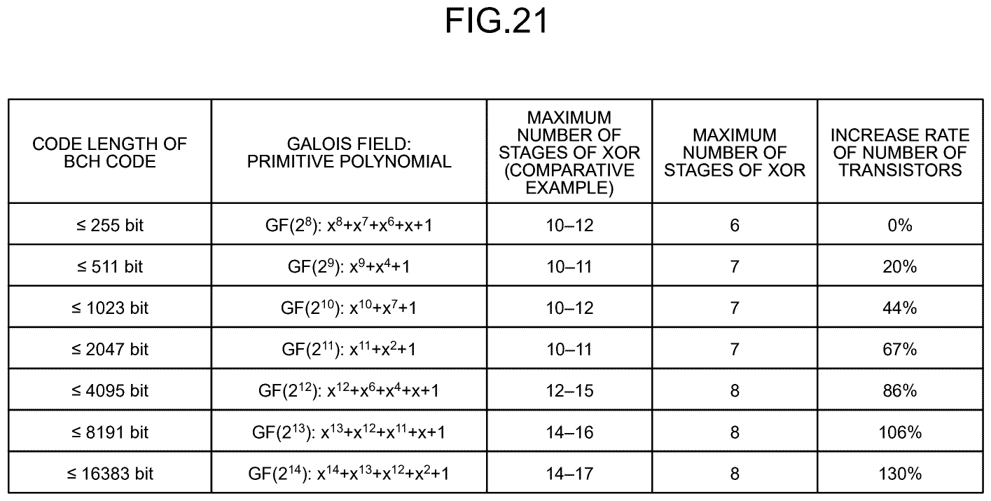

In the above, the comparison has been made in the number of stages with m=10. Even in any case other than the case of m=10, the number of stages of XOR operations can be reduced by applying the present embodiment. FIG. 21 is a table for describing examples of reductions in the number of stages with m=8 to 14.

FIG. 21 illustrates examples of the code length of the BCH code, examples of the primitive polynomial, examples of the maximum number of stages of XOR in the comparative example, examples of the maximum number of stages of XOR in the present embodiment, and examples of the increase rate of the number of transistors. Regarding the maximum number of stages of XOR in the comparative example, an estimate without an increase in the number of stages due to the XOR calculation unit 501 corresponding to the second power of the Galois field is described on the left and an estimate to which the number of stages of the XOR calculation unit 501 is added is described on the right. Note that FIG. 21 illustrates an example of the number of stages of arithmetic operation for calculation of a⁷ of the Galois field. In addition, the maximum number of stages of XOR corresponds to, for example, the number of stages of the XOR calculation unit 112 in the arithmetic unit 110.

As described above, the number of elements 2^{m} of the Galois field is defined in accordance with the code length n=2^{m}−1 of the BCH code. With m ranging from 8 to 14, the maximum number of stages of XOR in the comparative example is 10 minimum and 17 maximum. In contrast to this, in the present embodiment, the maximum number of stages of XOR ranges from 6 to 8, and thus, regardless of the values of m, the number of steps can be made smaller in the present embodiment than in the comparative example. A larger m causes an increase in the increase rate of circuit size (the number of transistors) due to replacement of multiplication (direct product and contraction). However, for example, in a case where an increase is made in the input/output bit width of the decoder 18 in order to enhance the entire decoder 18 in speed, the circuit size for which the arithmetic unit 110 (error locator polynomial calculation unit 102) accounts in the decoder 18 is relatively small. For this reason, the influence of an increase in the circuit size of the arithmetic unit 110 can be brought into an allowable range.

The configuration example of the arithmetic unit 110 that calculates a⁷ of the Galois field has been described above. This arithmetic unit 110 is configured based on direct product and contraction to two order-3 tensors as an example. The number of order-3 tensors to be subjected to direct product and contraction is not limited to two and thus may be three or more.

That is, the arithmetic unit 110 can be configured such that AND operations (AND calculation unit 111) and XOR operations (XOR calculation unit 112) perform an arithmetic operation (first arithmetic operation) corresponding to p multiplications to be performed in series that are represented, respectively, by p order-3 tensors (p is an integer of 2 or more). The AND operations correspond to an arithmetic operation that calculate the AND values of a plurality of elements for use in the p multiplications. The XOR operations correspond to an arithmetic operation based on a tensor obtained by contraction of an order-3p tensor obtained by a direct product of the p order-3 tensors (hereinafter, referred to as a contracted tensor) and an AND values resulting from the AND operations.

The contracted tensor can be interpreted as being obtained as follows. That is, the contracted tensor corresponds to a tensor obtained by contraction of an order-3p tensor to one or more sets in which an output from one order-3 tensor serves as an input to the other order-3 tensor from among plural sets each including two order-3 tensors selected from p order-3 tensors, with respect to an index corresponding to the output and an index regarding the input.

In addition, as an example, the arithmetic unit 110 that calculates a⁷ of the Galois field includes, as elements for use in p multiplications (two multiplications), one or more elements (first element) corresponding to the 2^{u}-th power of an element of the Galois field. The arithmetic unit 110 uses, for multiplication, an element a² corresponding to the second power of an element a (u=1) and an element a⁴ corresponding to the fourth power of the element a (u=2). In such a case, the arithmetic unit 110 is configured to use a tensor (contracted tensor) resulting from contraction of a direct product of an order-3p tensor and one or more order-2 tensors representing the 2^{u}-th power.

An arithmetic operation to be performed by the arithmetic unit 110 is not limited to the seventh power of an element of the Galois field. Hereinafter, a configuration example of the arithmetic unit 110 that performs an arithmetic operation different from the seventh power will be described.

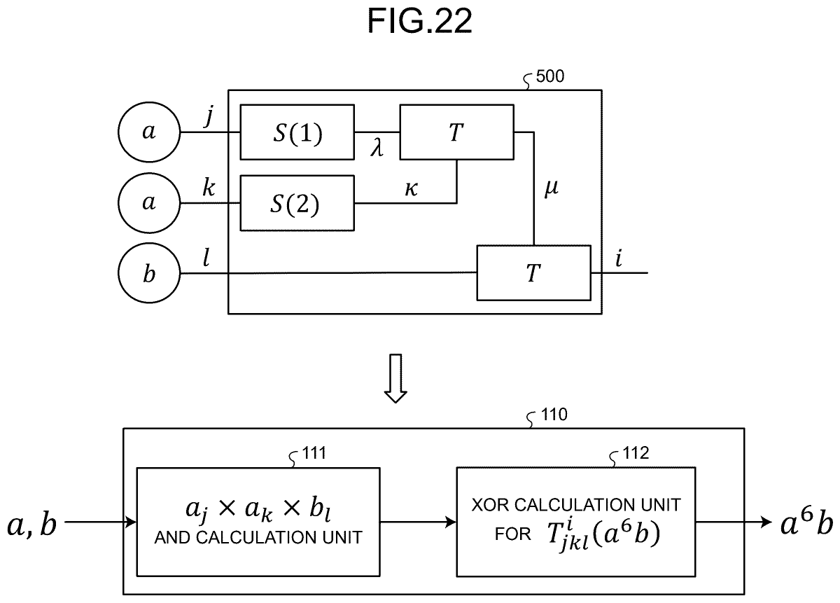

FIG. 22 is a diagram illustrating a configuration example of the arithmetic unit 110 that calculates a⁶b of the Galois field. Note that an example of the arithmetic unit 500 before tensor direct product and contraction are performed is illustrated in the upper part of FIG. 22.

a⁶b for which the arithmetic unit 110 in FIG. 22 performs an arithmetic operation is represented by the following Formula (10). In addition, a tensor Tⱼₖⁱ (a⁶b) in Formula (10) is represented by the following Formula (11). The tensor Tⱼₖₗⁱ(a⁶b) is an order-4 tensor for calculating a⁶b.

$${( {a}^{6} b )}_{i} = {\sum }_{j , k , l} {T}_{jkl}^{i} ( {a}^{6} b ) {a}_{j} {a}_{k} {b}_{i} \qquad ( 10 )$$

$${T}_{jkl}^{i} ( {a}^{6} b ) = {\sum }_{κ , λ , μ} {T}_{μ l}^{i} {T}_{λκ}^{μ} {S}_{k}^{κ} ( 2 ) {S}_{j}^{λ} ( 1 ) \qquad ( 11 )$$

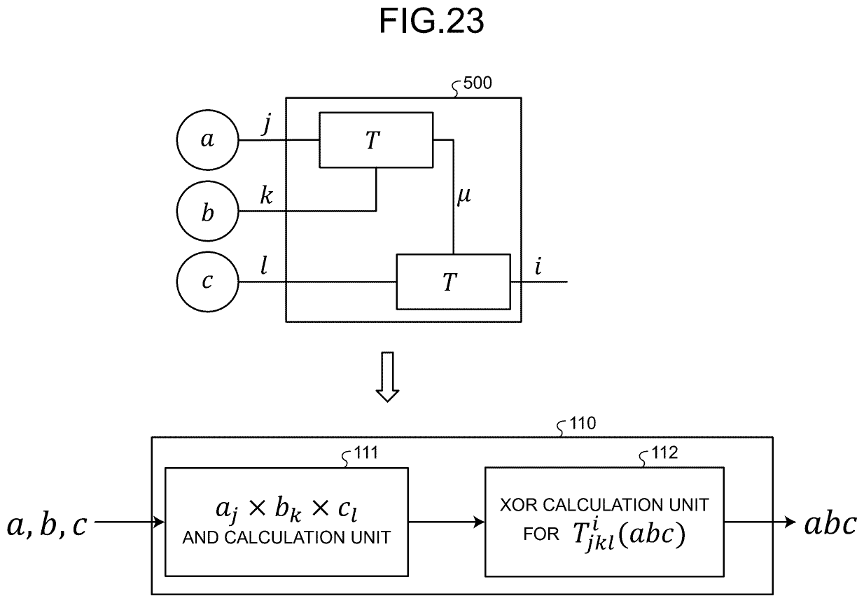

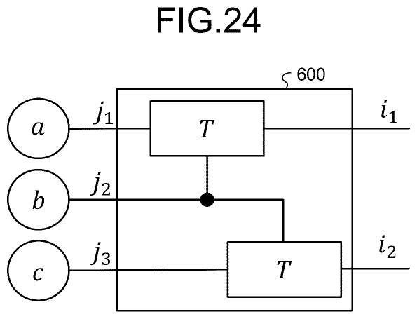

FIG. 23 is a diagram illustrating a configuration example of the arithmetic unit 110 that calculates abc of the Galois field. Note that an example of the arithmetic unit 500 before tensor direct product and contraction are performed is illustrated in the upper part of FIG. 23.

abc for which the arithmetic unit 110 in FIG. 23 performs an arithmetic operation is represented by the following Formula (12). In addition, a tensor Tⱼₖₗⁱ(abc) in the Formula (12) is represented by the following Formula (13). The tensor Tⱼₖₗⁱ(abc) is an order-4 tensor for calculating abc.

$${( abc )}_{i} = {\sum }_{j , k , l} {T}_{jkl}^{i} ( abc ) {a}_{j} {b}_{k} {c}_{l} \qquad ( 12 )$$

$${T}_{jkl}^{i} ( abc ) = {\sum }_{μ} {T}_{μ l}^{i} {T}_{jk}^{μ} \qquad ( 13 )$$

As an example, the arithmetic unit 500 in the comparative example illustrated in FIG. 18, 22, or 23 includes two steps of multiplication corresponding to two tensors T. Although an arithmetic operation corresponding to two tensors T is included, even without performing direct product and tensor contraction to these tensors, a single step of multiplication may be provided.

FIG. 24 is a diagram illustrating an example of an arithmetic unit 600 having such a configuration as described above. The arithmetic operation that the arithmetic unit 600 performs is represented by the following Formula (14).

$$( \begin{matrix}{( ab )}_{{i}_{1}} \\ {( bc )}_{{i}_{2}}\end{matrix} ) = ( \begin{matrix}{\sum }_{{j}_{1} , {j}_{2}} {T}_{{j}_{1} {j}_{2}}^{{i}_{1}} {a}_{{j}_{1}} {b}_{{j}_{2}} \\ {\sum }_{{j}_{2} , {j}_{3}} {T}_{{j}_{2} {j}_{3}}^{{i}_{2}} {b}_{{j}_{2}} {c}_{{j}_{3}}\end{matrix} ) \qquad ( 14 )$$

In the arithmetic unit 600, an arithmetic result from one tensor T is not used in the arithmetic operation of the other tensor T. For this reason, the arithmetic operation based on the two tensors T is not required to be performed in series. Thus, the arithmetic unit 600 can be configured such that the number of steps of multiplication is one. Such an arithmetic unit 600 does not need to perform such replacement of multiplication due to direct product and contraction as in the present embodiment.

Hereinafter, another example of an arithmetic unit to which such replacement of multiplication due to direct product and contraction as in the present embodiment can be applied will be described.

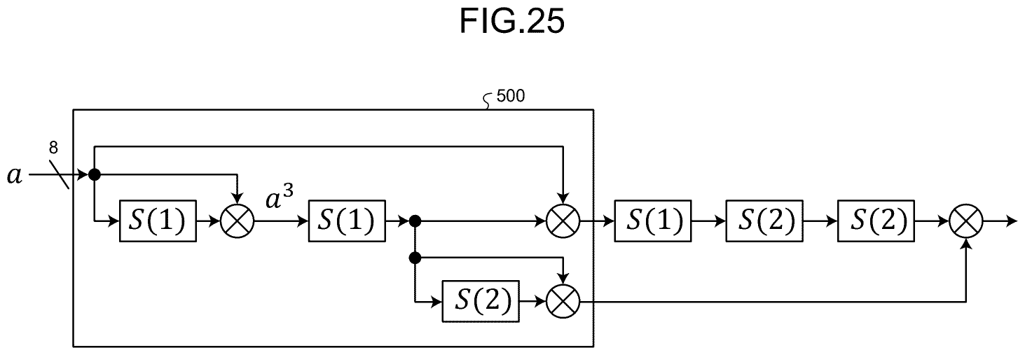

FIG. 25 is a diagram illustrating a configuration example of the arithmetic unit 500 that calculates an inverse element of an element a of the Galois field. Such an arithmetic unit 500 includes multiple times of multiplication to be performed in series (hereinafter, referred to as multiple steps of multiplication). Therefore, the transformation to a single step of multiplication in the present embodiment can be applied.

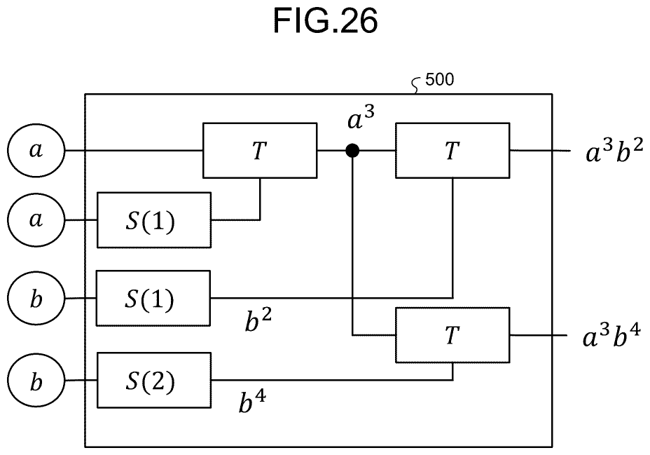

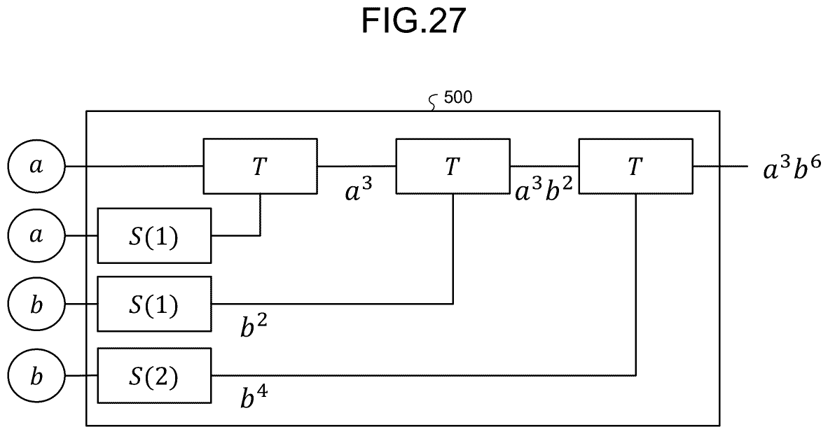

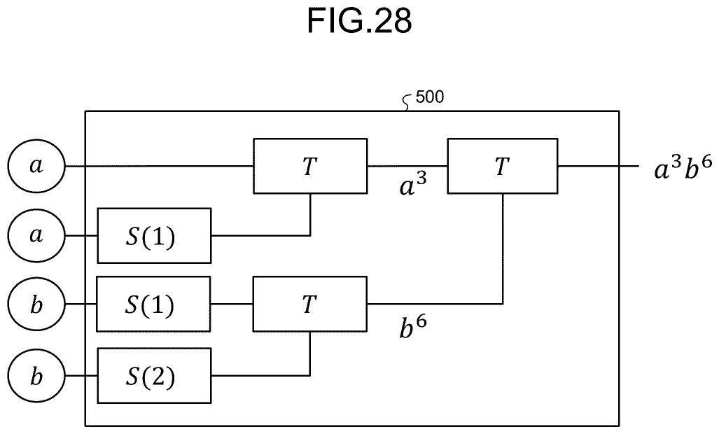

FIG. 26 is a diagram illustrating a configuration example of the arithmetic unit 500 that calculates a³b² and a³b⁴ of the Galois field. FIGS. 27 and 28 are each a diagram illustrating a configuration example of the arithmetic unit 500 that calculates a³b⁶ of the Galois field. The arithmetic unit 500 in each of FIGS. 26 to 28 includes three tensors T. Meanwhile, the arithmetic unit 500 in each of FIGS. 26 and 28 includes two steps of multiplication, and the arithmetic unit 500 in FIG. 27 includes three steps of multiplication. Thus, the number of included tensors T and the number of steps of multiplication do not necessarily match with each other. Even in any case, provided that the number of steps of multiplication is two or more, the replacement of multiplication in the present embodiment can be applied.

In FIG. 26, all the tensors included in the arithmetic unit 500 may be brought into a single AND calculation unit and a single XOR calculation unit due to direct product and contraction. Alternatively, either a set of the left tensor and the upper right tensor or a set of the left tensor and the lower right tensor may be brought into a single AND calculation unit and a single XOR calculation unit due to direct product and contraction. In FIG. 27, all the tensors included in the arithmetic unit 500 may be brought into a single AND calculation unit and a single XOR calculation unit due to direct product and contraction. Alternatively, either a set of the left tensor and the middle tensor or a set of the middle tensor and the right tensor may be brought into a single AND calculation unit and a single XOR calculation unit due to direct product and contraction. In FIG. 28, all the tensors included in the arithmetic unit 500 may be brought into a single AND calculation unit and a single XOR calculation unit due to direct product and contraction. Alternatively, either a set of the upper left tensor and the right tensor or a set of the lower left tensor and the right tensor may be brought into a single AND calculation unit and a single XOR calculation unit due to direct product and contraction.

Note that the configuration in FIG. 28 can be interpreted as an improved version of the configuration in FIG. 27 such that a smaller number of steps of multiplication are performed in a tournament style. As illustrated in FIG. 28, the number of steps of multiplication can be configured to be ceiling(log(the number of tensors T)). That is, similarly to the case of an XOR operation, adoption of a tournament style enables an arithmetic operation to be performed at higher speed.

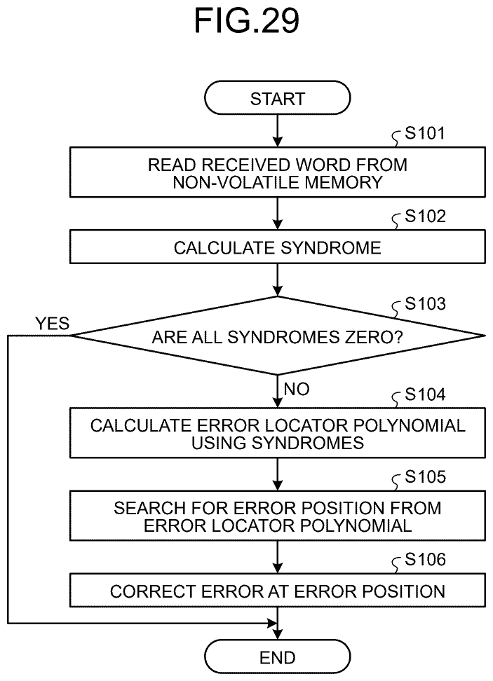

Next, a procedure of decoding processing in the memory system 1 will be described. FIG. 29 is a flowchart illustrating an example of decoding processing in the present embodiment.

The control unit 11 reads an error correction code from the non-volatile memory 20 and obtains a received word (step S101). In addition, the control unit 11 instructs the decoder 18 to start decoding.

The syndrome calculation unit 101 of the decoder 18 calculates a syndrome from the received word (step S102). The decoder 18 determines whether or not the values of all the calculated syndromes are zero (step S103).

In a case where all the syndromes are zero (step S103: Yes), it can be determined that no error exists in the received word, and thus the decoder 18 ends the decoding processing. In a case where all the syndromes are not zero (step S103: No), the error locator polynomial calculation unit 102 calculates an error locator polynomial by using the syndromes in accordance with the PGZ algorithm (step S104). In this case, for at least some of the coefficients of the error locator polynomial, the arithmetic unit 110 calculates the multiplication of syndromes.

The error position calculation unit 103 searches for an error position based on the calculated error locator polynomial (step S105). The bit flipping unit 104 corrects an error by inverting the bit at the error position obtained by the searching (by bit flipping) (step S106) and then ends the decoding processing.

As described above, according to the present embodiment, multiple times of multiplication of the Galois field can be performed at higher speed.

While certain embodiments have been described, these embodiments have been presented by way of example only, and are not intended to limit the scope of the inventions. Indeed, the novel embodiments described herein may be embodied in a variety of other forms; moreover, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. Arithmetic circuitry comprising:
circuitry configured to perform a first arithmetic operation by AND operations and XOR operations,
the first arithmetic operation corresponding to p multiplications to be performed in series, p being an integer of 2 or more, the p multiplications being respectively represented by p order-3 tensors each receiving two elements of a Galois field as inputs and outputting one element as a result of multiplication of the two elements,
the AND operations calculating AND values of a plurality of elements used in the p multiplications,
the XOR operations being based on a contracted tensor obtained by contraction of an order-3p tensor obtained by a direct product of the p order-3 tensors and the AND values.

2. The arithmetic circuitry according to claim 1, wherein
the plurality of elements includes one or more first elements corresponding to a 2^{u}-th power of an element of the Galois field, u being an integer of 1 or more, and
the contracted tensor is obtained by contraction of a direct product of the order-3p tensor and one or more order-2 tensors representing a 2^{u}-th power corresponding to the one or more first elements.

3. The arithmetic circuitry according to claim 2, wherein
the p order-3 tensors are each obtained by using a companion matrix determined in accordance with the Galois field, and
the one or more order-2 tensors are obtained by using the p order-3 tensors.

4. The arithmetic circuitry according to claim 1, wherein the contracted tensor is obtained by contraction of the order-3p tensor to one or more sets, in which an output from an order-3 tensor serves as an input to another order-3 tensor, from among multiple sets each including two order-3 tensors selected from the p order-3 tensors, the contraction being performed with respect to an index corresponding to the output and an index regarding the input.

5. The arithmetic circuitry according to claim 1, wherein the contracted tensor is represented by a matrix obtained by arranging one-dimensional vectors each being a vector in which a plurality of indices corresponding to a plurality of inputs is combined, the one-dimensional vectors being arranged such that a number of the one-dimensional vectors are identical to a number of elements of an index corresponding to one output.

6. A memory system comprising:
a non-volatile memory in which data having been encoded in an error correction code is stored; and
a memory controller including the arithmetic circuitry according to claim 1, the memory controller being configured to
calculate syndromes being elements of a Galois field by using a received word read from the non-volatile memory,
perform the first arithmetic operation by using the arithmetic circuitry with some of the syndromes as the plurality of elements,
calculate an error position by using an error locator polynomial having a coefficient including a result of the first arithmetic operation, and
correct an error at the error position calculated.

7. A method of controlling a non-volatile memory, the method comprising:
storing, in the non-volatile memory, data having been encoded in an error correction code;
reading, as a received word, the data from the non-volatile memory;
calculating syndromes being elements of a Galois field by using a received word read from the non-volatile memory;
performing the first arithmetic operation by using the arithmetic circuitry according to claim 1 with some of the syndromes as the plurality of elements;
calculating an error position by using an error locator polynomial having a coefficient including a result of the first arithmetic operation; and
correcting an error at the error position calculated.

8. The method according to claim 7, wherein
the plurality of elements includes one or more first elements corresponding to a 2^{u}-th power of an element of the Galois field, u being an integer of 1 or more, and
the contracted tensor is obtained by contraction of a direct product of the order-3p tensor and one or more order-2 tensors representing a 2^{u}-th power corresponding to the one or more first elements.

9. The method according to claim 8, wherein
the p order-3 tensors are each obtained by using a companion matrix determined in accordance with the Galois field, and
the one or more order-2 tensors are obtained by using the p order-3 tensors.

10. The method according to claim 7, wherein the contracted tensor is obtained by contraction of the order-3p tensor to one or more sets, in which an output from an order-3 tensor serves as an input to another order-3 tensor, from among multiple sets each including two order-3 tensors selected from the p order-3 tensors, the contraction being performed with respect to an index corresponding to the output and an index regarding the input.

11. The method according to claim 7, wherein the contracted tensor is represented by a matrix obtained by arranging one-dimensional vectors each being a vector in which a plurality of indices corresponding to a plurality of inputs is combined, the one-dimensional vectors being arranged such that a number of the one-dimensional vectors are identical to a number of elements of an index corresponding to one output.
